(19) United States
(12) Patent Application Publication
(10) Pub. No.: US 2018/0061618 A1
(43) Pub. Date: Mar. 1, 2018

(54) PLASMA SCREEN FOR PLASMA PROCESSING CHAMBER

(71) Applicant: Applied Materials, Inc., Santa Clara, CA (US)

(72) Inventors: Michael Thomas NICHOLS, Sunnyvale, CA (US); Imad YOUSIF, San Jose, CA (US); John Anthony O'MALLEY, III, San Jose, CA (US); Rajinder DHINDSA, Pleasanton, CA (US); Steven E. BABAYAN, Los Altos, CA (US)

(21) Appl. No.: 15/684,230

(22) Filed: Aug. 23, 2017

Related U.S. Application Data
(60) Provisional application No. 62/380,151, filed on Aug. 26, 2016.

(51) Int. Cl. H01J 37/32

(52) U.S. Cl. CPC H01J 37/32807; H01J 37/32449; H01J 37/32715; H01J 37/321

(57) ABSTRACT

Embodiments of the present disclosure relate to a plasma screen used in a plasma processing chamber with improved flow conductance and uniformity. One embodiment provides a plasma screen. The plasma screen includes a circular plate having a center opening and an outer diameter. A plurality of cut outs formed through the circular plate. The plurality of cut outs are arranged in two or more concentric circles. Each concentric circle includes equal number of cut outs.

### CROSS-REFERENCE TO RELATED APPLICATIONS

This application claims priority to U.S. Provisional Patent Application Ser. No. 62/380,151, filed on Aug. 26, 2016, which herein is incorporated by reference.

### BACKGROUND

### Field

Embodiments of the present disclosure relate to apparatus and methods for processing semiconductor substrates. More particularly, embodiments of the present disclosure relate to a plasma screen in a plasma processing chamber.

### Description of the Related Art

Electronic devices, such as flat panel displays and integrated circuits, commonly are fabricated by a series of processes in which layers are deposited on a substrate and the deposited material is etched into desired patterns. The processes commonly include physical vapor deposition (PVD), chemical vapor deposition (CVD), plasma enhanced CVD (PECVD), and other plasma processing. Specifically, a plasma process includes supplying a process gas mixture to a vacuum chamber, and applying electrical or electromagnetic power (RF power) to excite the process gas into a plasma state. The plasma decomposes the gas mixture into ion species that perform the desired deposition or etch processes.

One problem encountered with plasma processes is the difficulty associated with establishing uniform plasma density over the substrate surface during processing, which leads to non-uniform processing between the center and edge regions of the substrate and non-uniform processing from substrate to substrate.

Embodiments of the present disclosure relate to a plasma screen used in a plasma processing chamber to improve processing uniformity within a substrate and uniformity from substrate to substrate.

### SUMMARY

Embodiments of the present disclosure relate to a plasma screen used in a plasma processing chamber with improved flow conductance and uniformity.

One embodiment provides a plasma screen. The plasma screen includes a circular plate having a center opening and an outer diameter. A plurality of cut outs formed through the circular plate. The plurality of cut outs are arranged in two or more concentric circles, and total cut out areas of the plurality of cut outs in each concentric circle are substantially equal.

Another embodiment provides a plasma process chamber. The plasma includes a chamber body defining a process region, a substrate support having a substrate support surface facing the process region, and a plasma screen disposed around the substrate support surface, wherein the plasma screen comprises a circular plate having a center opening and a plurality of cut outs formed through, and the circular plate extends across an annular area between an outer region of the substrate support and an inner surface of the chamber body.

Another embodiment provides a method for processing a substrate. The method includes positioning a substrate on a substrate support in a plasma process chamber, and flowing one or more process gas through a flow path in the plasma chamber, wherein the flow path includes a plurality of cut outs in the a plasma screen disposed around the substrate, the plasma screen has a circular plate extending across an annular area between the substrate support and a chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic sectional view of a plasma process chamber according to one embodiment of the present disclosure.

FIG. 1B is a schematic partial perspective view of the plasma process chamber of FIG. 1A showing a plasma screen.

FIG. 1C is an enlarged partial view of FIG. 1A showing an electrical coupling mechanism between the plasma screen to other chamber component.

FIG. 2A is a schematic top view of a plasma screen according to one embodiment of the present disclosure.

FIG. 2B is a schematic sectional side view of the plasma screen of FIG. 2A.

FIG. 2C is a partial enlarged view of FIG. 2A showing one configuration of cut outs in the plasma screen of FIG. 2A.

FIG. 2D schematically illustrates another configuration of cut outs.

FIG. 2E schematically illustrates another configuration of cut outs.

FIG. 3A is a schematic partial view top view of a plasma screen according to another embodiment of the present disclosure.

FIG. 3B is a schematic partial sectional side view of the plasma screen of FIG. 3A.

FIG. 3C is a schematic partial top view of the plasma screen in an alternative configuration.

FIG. 3D is a schematic partial sectional view of the plasma screen in FIG. 3C.

FIG. 4A is a schematic top view of a plasma screen according to another embodiment of the present disclosure.

FIG. 4B is a schematic sectional side view of the plasma screen of FIG. 4A.

FIG. 4C is a schematic partial perspective view of the plasma screen of FIG. 4A installed in a plasma process chamber.

FIG. 4D is an enlarged partial view of FIG. 4C showing an electrical coupling mechanism between the plasma screen to other chamber component.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present disclosure generally relates to a plasma screen used in a plasma processing chamber. The plasma screen according to the present disclosure achieves improved process uniformity within a substrate and from substrate to substrate.

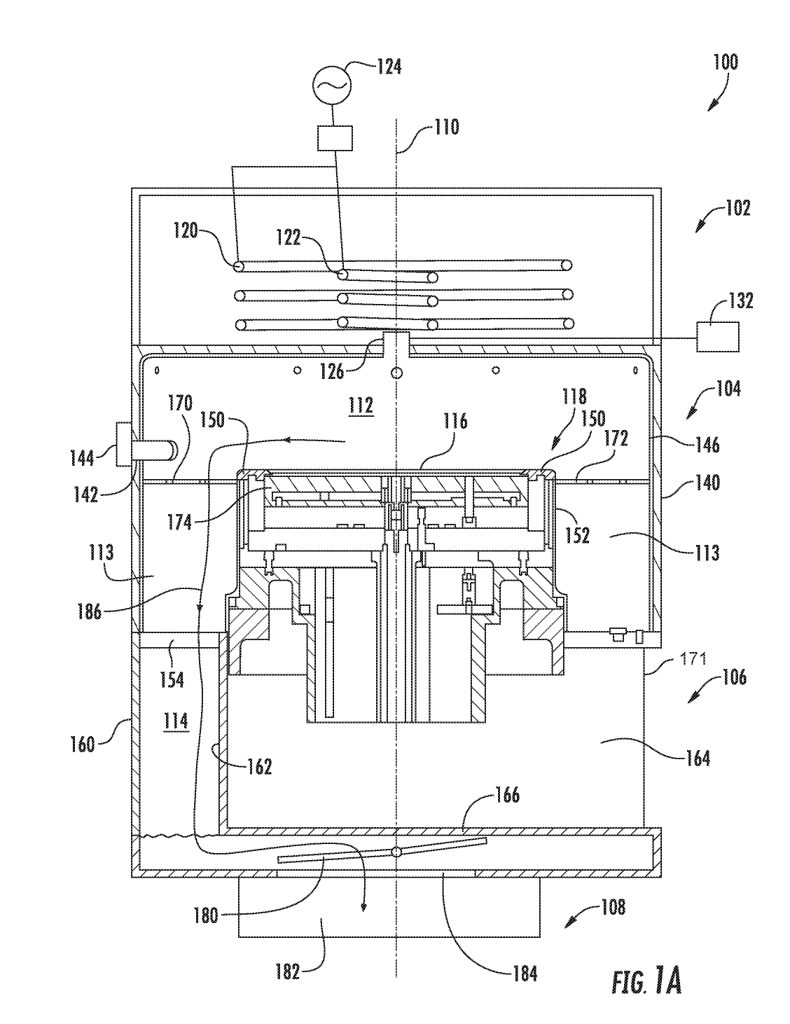

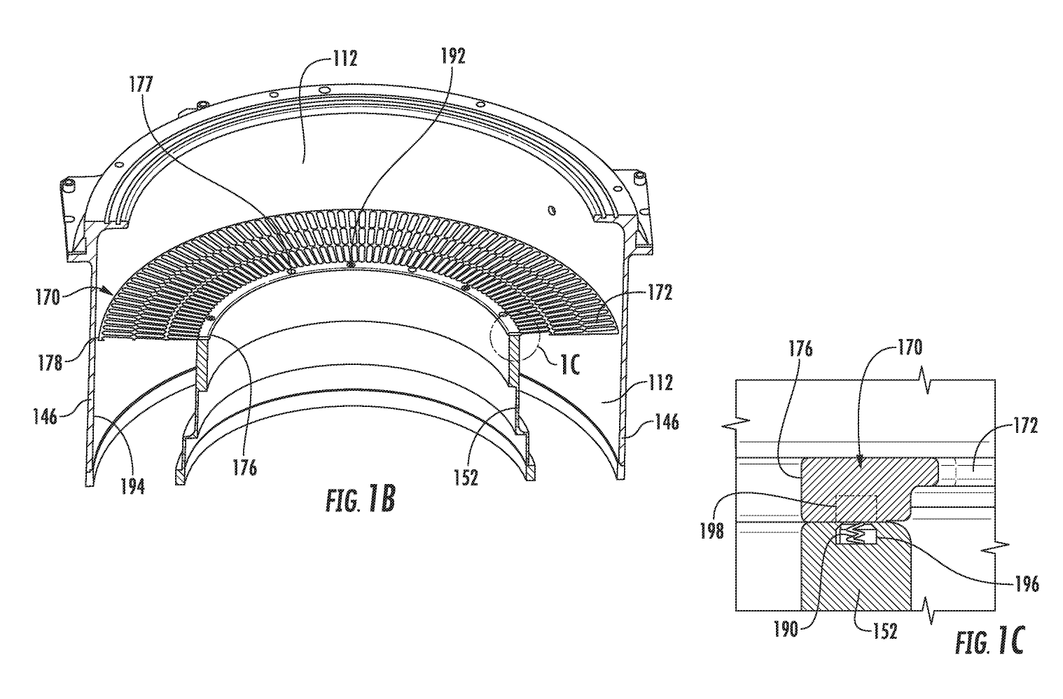

FIG. 1A is a schematic sectional view of a plasma process chamber 100 according to one embodiment of the present disclosure. The plasma process chamber 100 may be a plasma etch chamber, a plasma enhanced chemical vapor deposition chamber, a physical vapor deposition chamber, a plasma treatment chamber, an ion implantation chamber, or other suitable vacuum processing chamber.

The plasma process chamber 100 may include a source module 102, a process module 104, a flow module 106, and an exhaust module 108. The source module 102, the process module 104 and the flow module 106 collectively enclose a process region 112. During operation, a substrate 116 is positioned on a substrate support assembly 118 and exposed to process environment, such as plasma generated in the process region 112, to process the substrate 116. Exemplary process which may be performed in the plasma process chamber 100 may include etching, chemical vapor deposition, physical vapor deposition, implantation, plasma annealing, plasma treating, abatement, or other plasma processes. Vacuum is maintained in the process region 112 by suction from the exhaust module 108 through the flow module 106. The process region 112 may be substantially symmetrical about a central axis 110 to provide symmetrical electrical, gas, and thermal flow to establish uniform process conditions.

In one embodiment, as shown in FIG. 1A, the source module 102 may be an inductively coupled plasma source. The source module 102 may include an outer coil assembly 120 and an inner coil assembly 122. The outer coil assembly 120 and the inner coil assembly 122 may be connected to a RF (radio frequency) power source 124. A gas inlet tube 126 may be disposed along the central axis 110. The gas inlet tube 126 may be connected to a gas source 132 to supply one or more processing gases to the process region 112.

Even though an inductive plasma source is described above, the source module 102 may be any suitable gas/plasma source according to a process requirement. For example, the source module 102 may be a capacitively coupled plasma source, a remote plasma source, or a microwave plasma source.

The process module 104 is coupled to the source module 102. The process module 104 may include a chamber body 140 enclosing the process region 112. The chamber body 140 may be fabricated from a conductive material resistant to processing environments, such as aluminum or stainless steel. The substrate support assembly 118 is centrally disposed within the chamber body 140 and positioned to support the substrate 116 in the process region 112 symmetrically about the central axis 110.

A slit valve opening 142 is formed through the chamber body 140 to allow passages of the substrate 116. A slit valve 144 may be disposed outside the chamber body 140 to selectively open and close the slit valve opening 142.

In one embodiment, an upper liner assembly 146 may be disposed within an upper portion of the chamber body 140 shielding the chamber body 140 from the process environment. The upper liner assembly 146 may be constructed from a conductive, process compatible material, such as aluminum, stainless steel, and/or yttria (e.g., yttria coated aluminum).

The flow module 106 is attached to the process module 104. The flow module 106 provides flow paths between the process region 112 and the exhaust module 108. The flow module 106 also provides an interface between the substrate support assembly 118 and the atmospheric environment exterior to the plasma process chamber 100.

The flow module 106 includes an outer wall 160, an inner wall 162, two or more pairs of radial walls 164 connecting between the inner wall 162 and the outer wall 160, and a bottom wall 166 attached to the inner wall 162 and the two or more pairs of radial walls 164. The outer wall 160 may include two or more through holes 171 formed between each pair of radial walls 164. A chassis 154 is sealingly disposed over the inner wall 162 and the two or more pairs of radial walls 164. The substrate support assembly 118 may be disposed over the chassis 154.

The outer wall 160 and the inner wall 162 may be cylindrical walls concentrically arranged. When assembled, a central axis of the outer wall 160 and the inner wall 162 coincides with the central axis 110 of the plasma process chamber 100. The inner wall 162, bottom wall 166, radial walls 164 and the chassis 154 divide the inner volume of the outer wall 160 into evacuation channels 114 and atmosphere volume 168. The evacuation channels 114 connect with the process region 112 of the process module 104.

The exhaust module 108 includes a symmetric flow valve 180 and a vacuum pump 182 attached to the symmetric flow valve 180 through a pump port 184. The symmetric flow valve 180 connects to the evacuation channels 114 to provide symmetric and uniform flow in the plasma process chamber 100. During operation, processing gas flow through the process chamber 100 along a flow path 186.

The substrate support assembly 118 is positioned along the central axis 110 to position the substrate 116 symmetrically about the central axis 110. The substrate support assembly 118 is supported by the chassis 154. The substrate support assembly 118 may include an edge ring 150 disposed around a support plate 174. A substrate support liner 152 may be disposed around the substrate support assembly 118 to shield the substrate support assembly 118 from the process chemistry.

A plasma screen 170 may be disposed around the substrate support assembly 118 to confine the plasma above the substrate 116. In one embodiment, the plasma screen 170 may be disposed to cover an entrance of an annular volume 113 between the substrate support liner 152 and the upper liner assembly 146. The plasma screen 170 includes a plurality of cut outs 172 configured to direct gas flow from the process region 112 to the annular volume 113. In one embodiment, the plasma screen 170 may be attached to the upper liner assembly 146 like a flange.

FIG. 1B is a schematic partial perspective view of the plasma process chamber 100 showing the plasma screen 170. The plasma screen 170 may be attached to the substrate support assembly 118. The plasma screen 170 may be a circular plate having a center opening 176 and an outer diameter 178. A plurality of screw holes 177 may be formed around the center opening 176. The plasma screen 170 may be attached to the substrate support liner 152 by a plurality of screws 192. Other attachment features may be used in place of screw holes 177 and screws 192. The outer diameter 178 is sized to match an inner diameter 194 of the upper liner assembly 146. In one embodiment, the outer diameter 178 is slightly smaller than the inner diameter 194 of the upper liner assembly 146 with an installation clearance to avoid surface damage during installation. In one embodiment, the clearance between the outer diameter 178 and the inner diameter 194 may be about 0.135 inches.

The plasma screen 170 may be formed from conductive material to facilitate a RF return path in the plasma process chamber 100. For example, the plasma screen 170 may be formed from a metal, such as aluminum. In one embodiment, the plasma screen 170 may have a protective coating that is compatible with processing chemistry. For example, the plasma screen 170 may have a ceramic coating, such as an yttria coating or an alumina coating.

In one embodiment, a conductive gasket 190 may be disposed between the plasma screen 170 and the substrate support liner 152 to ensure continuous electrical connection around the entire central opening 176. The conductive gasket 190 may be formed by a metal, such as aluminum, copper, steel. FIG. 1C is an enlarged partial view of FIG. 1A showing the conductive gasket 190. In FIG. 1C, the conductive gasket 190 is disposed in a groove 196 formed in the substrate support liner 152. Alternatively, the conductive gasket 190 maybe formed in a groove 198 formed in the plasma screen 170. Alternatively, both of the substrate support liner 152 and the plasma screen 170 may include a groove to house the conductive gasket 190 therein.

The plurality of cut outs 172 may be formed through the plasma screen 170 to allow fluid flow through the plasma screen 170. A total area of the cut outs 172 provides a flow area through the plasma screen 170. Depending on the flow area, the plasma screen 170 may affect fluid conductance of the fluid flow in the process chamber 100. When the flow area through the plasma screen 170 is equal to or greater than the narrowest area in the flow path 186, typically an area of the pump port 184, the plasma screen 170 does not affect fluid conductance of the process chamber 100. However, when the flow area through the plasma screen 170 is smaller than the narrowest area in the flow path 186, the plasma screen 170 chokes the gas flow along the flow path 186. In one embodiment, the shape and/or number of the plurality of cut outs 172 may be selected obtain a target flow area through the plasma screen 170.

On the other hand, the effectiveness of the plasma screen 170 on plasma retention depends on a total area of the conductive body of the plasma screen 170. The larger the total area of the conductive body, the more effective is the plasma screen 170 in retaining the plasma. Therefore, increasing the flow area through the plasma screen 170 may cause the plasma screen 170 to be less effective in plasma retention while reducing the flow are through the plasma screen 170 may promote the plasma screen to be more effective in plasma retention. Depending on the process requirement, the shape and/or number of the cut outs 172 may be selected to achieve desired effect on chamber fluid flow and plasma retention.

Additionally, the cut outs 172 may be arranged various patterns to achieve a target fluid conductance profile. In one embodiment, the cut outs 172 may be arranged to provide a uniform fluid conductance. Alternatively, the cut outs 172 may be arranged to have variable fluid conductance along the azimuthal and/or radial direction. Variable fluid conductance may be used to compensate non-uniformities in the process chamber 100 to achieve uniform processing.

In FIG. 1B, the cut outs 172 are elongated holes arranged in rows. In one embodiment, the cut outs 172 are in substantially identical shapes and evenly distributed in each row. Other shapes and/or patterns may be used to achieve a target effect on fluid flow.

During operation, one or more processing gases from the gas source 132 enter the process region 112 through the inlet conduit 126. A RF power may be applied to the outer and inner coil assemblies 120, 122 to ignite and maintain a plasma in the process region 112. The substrate 116 disposed on the substrate support assembly 118 is processed by the plasma. The one or more processing gases may be continuously supplied to the process region 112 and the vacuum pump 182 operates through the symmetric flow valve 180 and the flow module 106 to generate a symmetric and uniform gas flow over the substrate 116. The cut outs 172 in the plasma screen 170 allow processing gas to flow from the process region 112 to the annular volume 113 then to the evacuation channels 114 in the flow module 106 while the conductive body of the plasma screen 170 confines the plasma in the process region 112.

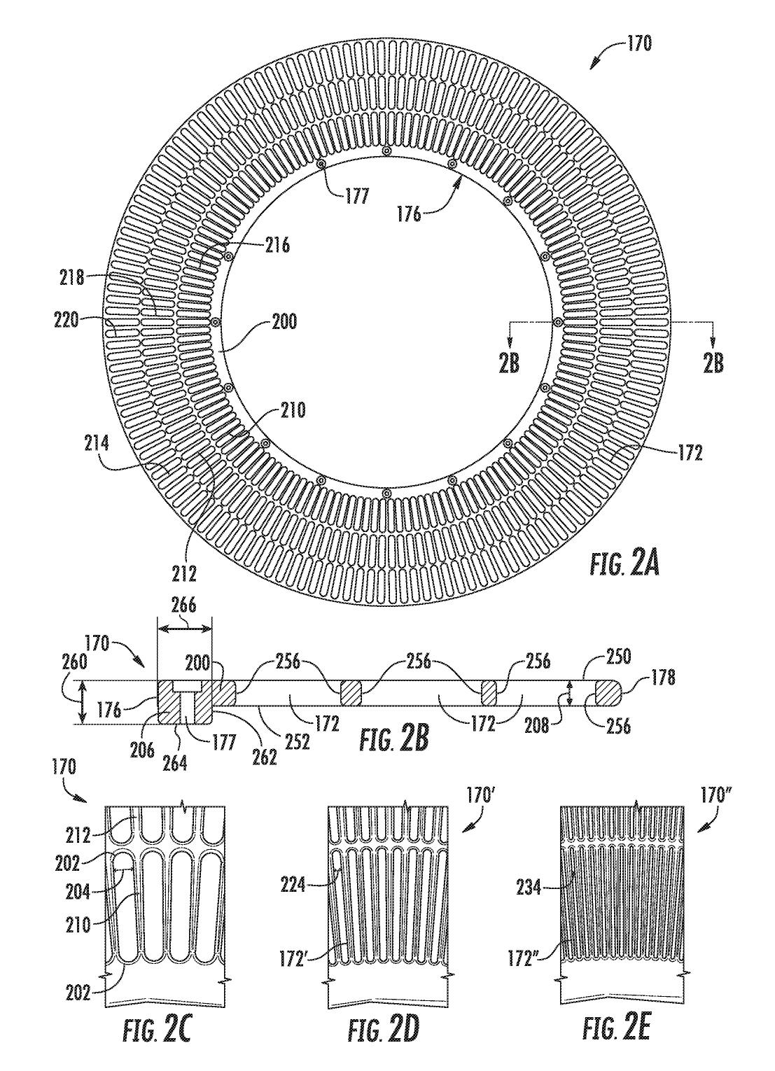

FIG. 2A is a schematic top view of the plasma screen 170 according to one embodiment of the present disclosure. FIG. 2B is a schematic sectional side view of the plasma screen 170. The plasma screen 170 has a conductive body 200. The conductive body 200 may be a circular plate having a thickness 208. The center opening 176 is formed through the conductive body 200. In one embodiment, the conductive body 200 may have a lip 206 around the center opening 176. The plurality of screw holes 177 may be formed through lip 206. The lip 206 may have a thickness 260. The thickness 260 is greater thickness than the thickness 208 of the conductive body 200. In one embodiment, the thickness 260 may be about 1.5 to about 3.0 times the thickness 208. The lip 206 may have a width 266 sufficient enough for the plurality of screw holes 177.

The conductive body 200 may be formed from a metal, such as aluminum. In one embodiment, the conductive body 200 may include a coating. The coating may be formed on all surfaces of the conductive body 200 that are exposed to process chemistry during operation. For example, the coating may be formed on an upper surface 250, a lower surface 252, and on walls 256 of the cut outs 172. In one embodiment, the coating may be a protective coating that is compatible with the process chemistry. In one embodiment, the coating may be a ceramic coating, such as an yttria coating or an alumina coating.

In the embodiment of FIG. 2B, the lip 206 extends from the lower surface 252 of the conductive body 200 such that a lower surface 264 of the lip 206 is below the lower surface 252 forming a shoulder 262. Alternatively, the lip 206 may extend from the upper surface 250 of the conductive body 200. For example, the width 266 may be between 5 mm to about 15 mm.

FIG. 2C is a partial enlarged view of the plasma screen 170 showing the shape and configuration of the cut outs 172. In one embodiment, the cut out 172 may be an elongated slot having rounded ends 202 and a width 204. In one embodiment, the plurality of cut outs 172 may be substantially identical in shape. The plurality of cut outs 172 may be arranged in three concentric circles 216, 218, 220. Even though three concentric circles are described here, more or less concentric circle may be used. In each concentric circles 216, 218, 220, the plurality of cut outs 172 may be separated by spokes 210, 212, 214 respectively. In one embodiment, the plurality of cut outs 172 may be evenly distributed each concentric circle 216, 218, 220.

In one embodiment, total cut out area of the plurality of cut outs 172 in each concentric circle 216, 218, 220 is substantially equal. For example, the cut outs 172 in each concentric circles 216, 218, 220 are of the same shape and equal numbers. As a result, the spokes 210, 212, 214 are of different dimensions. The spokes 212 are thicker than the spokes 210 and the spokes 214 are thicker than the spokes 212.

As discussed above, the cut outs 172 are formed through the conductive body 200 to provide fluid conductance. Fluid conductance rate of the plasma screen 170 may be denoted by dividing a total area of the cut outs 172 by an area of the pump port 184 or the narrowest flow area from the process region 112 to the vacuum pump 182. For example, the fluid conductance rate of the plasma screen is 100% when the total area of the cut outs 172 equals to or greater than the area of the pump port 184. The fluid conductance rate of the plasma screen is 50% when the total area of the cut outs 172 is 50% of the area of the pump port 184. The fluid conductance rate of the plasma screen 170 may be changed by changing the total area of the cut outs 172. The total area of the cut outs 172 may be changed by changing the shape and/or the number of the cut outs 172.

In the configuration of FIG. 2C, the dimension and number of the cut outs 172 may be selected to obtain 100% fluid conductance rate so that the plasma screen 170 impose minimal additional resistance towards the fluid flow in a process chamber.

FIG. 2D schematically illustrates a partial enlarged top view of a plasma screen 170′ according to another embodiment of the present disclosure. The plasma screen 170′ is similar to the plasma screen 170 except the plasma screen 170′ has cut outs 172′ with different dimension and number. Each cut out 172′ has a width 224 that is narrower than the width 204. There are more cut outs 172′ in the plasma screen 170′ than cut outs 172 in the plasma screen 170. As a result, the plasma screen 170′ has weaker fluid conductance and stronger plasma retention than the plasma screen 170. In one embodiment, the width 224 may be about 40% of the width 204 and the number of cut outs 172′ is twice as many as the number of cut outs 172, resulting in the plasma screen 170′ has a fluid conductance rate of 82% of the fluid conductance of the plasma screen 170.

FIG. 2E schematically illustrates a partial enlarged top view of a plasma screen 170″ according to another embodiment of the present disclosure. The plasma screen 170″ is similar to the plasma screen 170, 170′ except the plasma screen 170″ has cut outs 172″ with different dimension and number. Each cut out 172″ has a width 234 that is narrower than the width 204, 224. There are more cut outs 172″ in the plasma screen 170″ than cut outs 172, 172′ in the plasma screen 170, 170′. As a result, the plasma screen 170″ has weaker fluid conductance and stronger plasma retention than the plasma screen 170, 170′. In one embodiment, the width 234 may be about 16% of the width 204 and 40% of the width 224 and the number of cut outs 172′ is three times as many as the number of cut outs 172 and 1.5 times as many as the number of cut outs 172′, resulting in the plasma screen 170″ has a fluid conductance of 53% of the fluid conductance of the plasma screen 170 and 65% of the fluid conductance of the plasma screen 170′.

The plasma screens 170, 170′, 170″ may be used interchangeably in a plasma process chamber, such as the plasma process chamber 100, according to process requirement.

Even though the plasma screens described above have elongated cut outs, cut outs with other shapes, such as circular, oval, triangular, rectangular, or any suitable shapes, may be used. Even though, the cut outs described above are arranged in concentric circles, other patterns may be used to achieve desired effect.

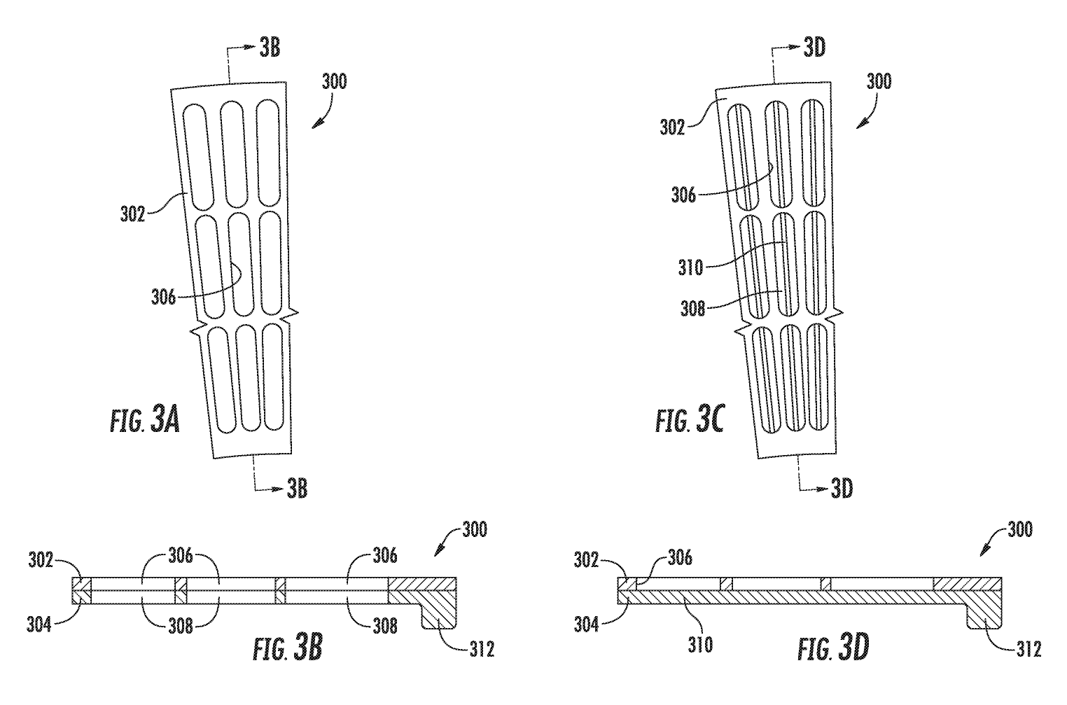

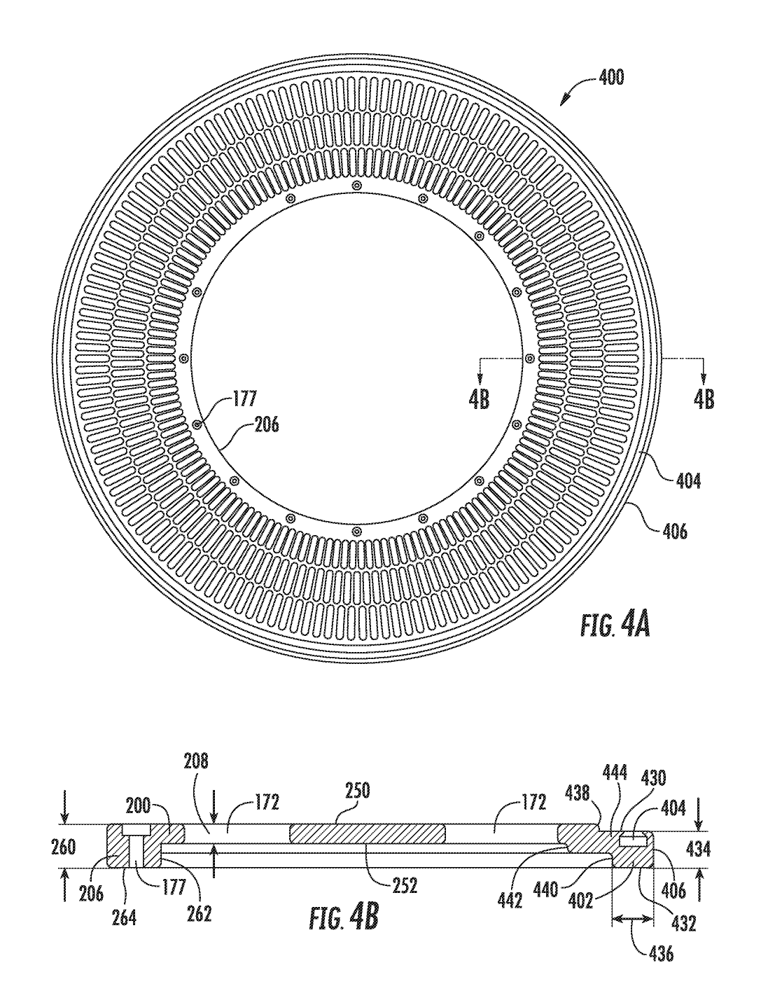

FIG. 3A is a schematic partial view top view of a plasma screen 300 according to another embodiment of the present disclosure. FIG. 3B is a schematic partial sectional side view of the plasma screen 300. The plasma screen 300 includes an upper plate 302 and a lower plate 304 stacked together. The upper plate 302 may be a planar plate. The lower plate 304 may have a lip 312 near an inner diameter. Similar to the plasma screen 170, each of the upper plate 302 and lower plate 304 has a conductive body having a plurality of cut outs 306, 308 formed therethrough. The cut outs 306, 308 may be identical in shape and arranged in identical pattern. In FIGS. 3A, 3B, the cut outs 306 in the upper plate 302 are aligned with the cut outs 308 in the lower plate 304. The stacked upper and lower plates 302 and 304 provide improve plasma retention compared to the upper plate 302 or the lower plate 304 alone because of the increased thickness.

FIG. 3C is a schematic partial top view of the plasma screen 300 in an alternative position when the cut outs 306 are not aligned with the cut outs 308. FIG. 3D is a schematic partial sectional view of the plasma screen 300 in the position of FIG. 3C. In FIG. 3C, 3D, the cut outs 306, 308 are staggered so that spokes 310 in the lower plate 304 block a portion of each cut out 306 in the upper plate 302 reducing flow area of the plasma screen 300, therefore reducing flow conductance. The exposed spokes 310 also increase the effectiveness of plasma retention.

The plasma screen 300 may be configured in the position of FIGS. 3A, 3B or the position of FIGS. 3C, 3D according to process requirement.

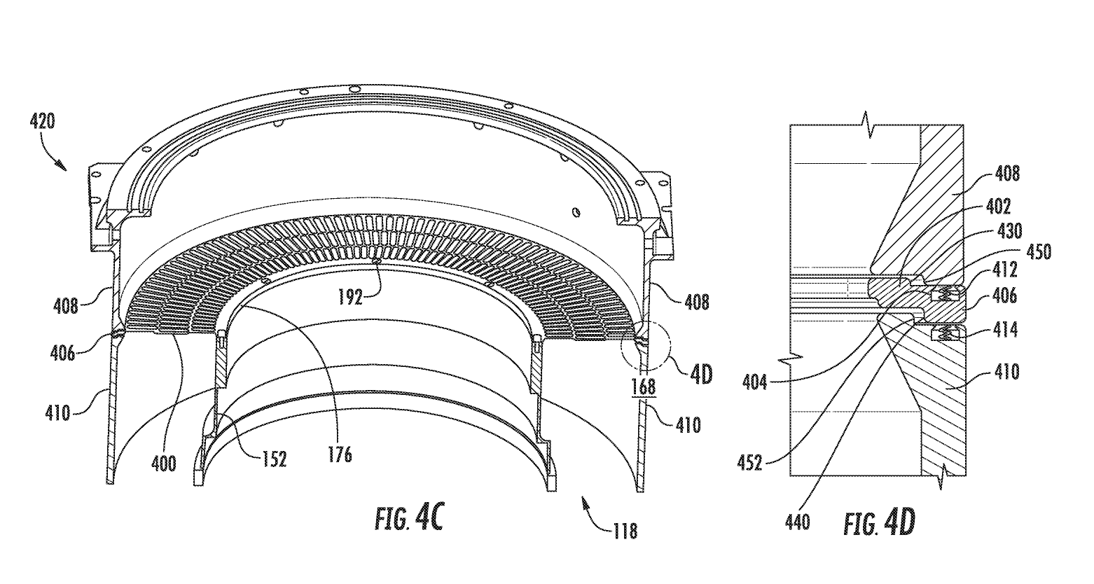

FIG. 4A is a schematic top view of a plasma screen 400 according to another embodiment of the present disclosure. FIG. 4B is a schematic sectional side view of the plasma screen 400. The plasma screen 400 is similar to the plasma screen 170 except the plasma screen 400 includes an outer lip 402 allowing the plasma screen 400 to conductively couple to a chamber component near an outer diameter 406 of the plasma screen 400. As shown in FIG. 4B, the outer lip 402 may have an upper surface 430, a lower surface 432, and a thickness 434 between the upper surface 430 and the lower surface 432. The thickness 434 may be greater than the thickness 208 of the conductive body 200. In one embodiment, the thickness 434 may be between 1.5 times and 3.0 times the thickness 208.

In one embodiment, the upper surface 430 of the outer lip 402 may be lower than the upper surface 430 of the conductive body to form a shoulder 438. The shoulder 438 may be used to align the plasma screen 400 with chambers.

In one embodiment, a groove 404 may be formed on the upper surface 430 of the plasma screen 400 near the outer diameter 406. The groove 404 may receive a conductive gasket to ensure continuous conductive coupling and/or to form a seal. The outer lip 402 may have a width 436 sufficient to form the groove 404. For example, the width 436 of the outer lip 402 may be between about 5 mm and about 15 mm.

As shown in FIG. 4B, the outer lip 402 extends below from the lower surface 252 of the conductive body 200 forming a shoulder 440. The shoulder 440 may be used to align the plasma screen 400 with a plasma chamber.

In the embodiment of FIG. 4B, a bridge section 444 may be connected between the conductive body 200 and the outer lip 402. The bridge section 444 is defined between the upper surface 430 and a lower surface 446. The bridge section 444 may have a thickness similar to the thickness 208 of the conductive body 200. The bridge section 444 may extend radially outward from the conductive body 200 through shoulders 442, 438. The bridge section 444 may increase rigidity of the plasma screen 400 without increasing weight.

FIG. 4C is a schematic partial perspective view of the plasma screen 400 installed in a plasma process chamber 420. The plasma process chamber 420 may be similar to the plasma process chamber 100 except the upper liner assembly 146 in the plasma process chamber 100 is replaced by an upper liner 408 and a lower liner 410. As shown in FIG. 4C, the plasma screen 400 may be attached to the substrate support liner 152 by a plurality of screws 192 near the center opening 176 and to the upper liner 408 and lower liner 410 near the outer diameter 406.

FIG. 4D is an enlarged partial view of FIG. 4C the connection near the outer diameter 406. The outer lip 402 may be placed between the upper liner 408 and the lower liner 410. The shoulder 438 of the plasma screen 400 aligns with a shoulder 450 of the upper liner 408. The shoulder 440 of the plasma screen 400 aligns with a shoulder 452 of the lower liner 410. In one embodiment, a conductive gasket 412 may be disposed in the groove 404 in the plasma screen 400. Similarly, a conductive gasket 414 between the plasma screen 400 and the lower liner 410.

In the configuration of FIG. 4C, the plasma screen 400 is attached to the upper liner 408 and lower liner 410 without any gap in between, therefore improving plasma retention. Additionally, the connective coupling between the plasma screen 400 and the upper liner 408, lower liner 410 provides a continuous and symmetric RF return path for the plasma in the plasma process chamber 420, thus, further improve processing uniformity.

Alternatively, the upper surface 430 of the outer lip 402 may protrude from or stay coplanar with the upper surface 250 of the conductive body 200 such that the upper surface 430 is above the upper surface 250 while the lower surface 432 of the outer lip 402 stays coplanar with or steps below the lower surface 252 of the conductive body 200.

Plasma screens according to embodiment of the present disclosure improve process uniformity. Particularly, plasma screens according to the present disclosure maintain consistent plasma uniformity in the process region over time, thus reducing critical dimension drift (CD drift) overtime, reducing wafer to wafer variation. The plasma screens also function effectively under a wide range of chamber pressure.

While the foregoing is directed to embodiments of the present disclosure, other and further embodiments of the disclosure may be devised without departing from the basic scope thereof, and the scope thereof is determined by the claims that follow.

What is claimed is:

1. A plasma screen, comprising:
a circular plate having a center opening and an outer diameter, wherein a plurality of cut outs formed through the circular plate, the plurality of cut outs are arranged in two or more concentric circles, and total cut out areas of the plurality of cut outs in each concentric circle are substantially equal.

2. The plasma screen of claim 1, wherein the cut outs are elongated slots.

3. The plasma screen of claim 2, wherein each elongated cut outs include round ends.

4. The plasma screen of claim 1, wherein the circular plate is formed from a conductive material.

5. The plasma screen of claim 4, further comprising a coating formed on one or more outer surface of the circular plate.

6. The plasma screen of claim 1, further comprising an inner lip around the center opening.

7. The plasma screen of claim 6, wherein the inner lip has one or more coupling features.

8. The plasma screen of claim 1, further comprising an outer lip formed near the outer diameter.

9. The plasma screen of claim 1, further comprising a lower circular plate stacked against the circular plate, wherein the lower circular plate includes a plurality of lower cut outs matching the cut outs in the circular plate.

10. A plasma process chamber, comprising:
a chamber body defining a process region;
a substrate support having a substrate support surface facing the process region; and
a plasma screen disposed around the substrate support surface, wherein the plasma screen comprises a circular plate having a center opening and a plurality of cut outs formed through, and the circular plate extends across an annular area between an outer region of the substrate support and an inner surface of the chamber body.

11. The plasma process chamber of claim 10, wherein the plurality of cut outs are arranged in two or more concentric circles, and each concentric circle include equal number of cut outs.

12. The plasma process chamber of claim 11, wherein the plurality of cut outs have identical shapes.

13. The plasma process chamber of claim 10, further comprising a conductive gasket, wherein the conductive gasket is disposed around the center opening to form a continuous coupling between the circular plate and a chamber component.

14. The plasma process chamber of claim 10, wherein the circular plate further comprises an outer lip formed around an outer diameter, and the outer lip is attached to a chamber component.

15. The plasma process chamber of claim 14, wherein the chamber component is a liner disposed inside the chamber body around the process region.

16. The plasma process chamber of claim 10, wherein the plasma screen comprises a lower plate stacked together with the circular plate, the lower plate has a plurality of lower cut outs identical to the plurality of cut outs.

17. A method for processing a substrate, comprising:
positioning a substrate on a substrate support in a plasma process chamber; and
flowing one or more process gas through a flow path in the plasma chamber, wherein the flow path includes a plurality of cut outs in the plasma screen disposed around the substrate, the plasma screen has a circular plate extending across an annular area between the substrate support and a chamber body.

18. The method of claim 17, further comprising generating a plasma in the process chamber.

19. The method of claim 17, further comprising reducing a total area of the cut outs to improve plasma retention.

20. The method of claim 17, further comprising providing an RF return path through the plasma screen.
